(19) United States
(12) Patent Application Publication
(10) Pub. No.: US 2026/0172141 A1
(43) Pub. Date: Jun. 18, 2026

(54) GOLD CODE SEQUENCE ERROR CORRECTION IN A NOISY CHANNEL

(71) Applicant: NVIDIA Corporation, Santa Clara, CA (US)

(72) Inventor: Raanan Ivry, Caesarea (IL)

(21) Appl. No.: 18/982,316

(22) Filed: Dec. 16, 2024

(51) Int. Cl. H04L 1/00

(52) U.S. Cl. CPC H04L 1/0045; H04L 1/0056

(57) ABSTRACT

Technologies for providing Gold code sequences error correction in a noisy channel are described. A receiver device includes an error correction circuit that receives an incoming Gold code sequence. The incoming Gold code sequence includes an error at a specific bit position. The error correction circuit can generate a plurality of Gold code sequences using the incoming Gold code sequence and delayed versions of the incoming Gold code sequence, each delayed version being delayed by a different amount such that each of the plurality of Gold code sequences comprises errors at different bit positions than the specific bit position. The error correction circuit can generate a corrected Gold code sequence using the plurality of Gold code sequences.

### RELATED APPLICATIONS

This application is related to U.S. patent application Ser. No. [not yet assigned], filed concurrently, entitled “Pseudo-Random Bit Sequence (PRBS) Error Correction in a Noisy Channel,” Attorney Docket No. 38724.950(L 0950.1 ).

### TECHNICAL FIELD

At least one embodiment pertains to processing resources used to perform pseudo-random sequence (PRS) error correction in a noisy channel. For example, at least one embodiment pertains to receiver devices that generate delayed versions of a PRBS and perform operations to generate a corrected PRBS. For another example, at least one embodiment pertains to receiver devices that generate delayed versions of a Gold code sequence and perform operations to generate a corrected Gold code sequence.

### BACKGROUND

Pseudo-random sequences (PRS) or Pseudo-Noise (PN) sequences are deterministic sequences that exhibit random-like properties and are widely used in communication, signal processing, and testing systems. In communication systems, a receiver can lock onto a Pseudo-Random Sequence (PRBS) for synchronization, signal detection, error measurement, data recovery, spread-spectrum communications, channel estimation, etc. The receiver can correlate an incoming signal with a locally generated PRBS. A peak in the correlation indicates alignment. If the PRBS is cyclic, the receiver adjusts the phase of its locally generated PRBS to match the incoming signal. A Phase-Locked Loop (PLL) or similar feedback mechanism may be used to maintain synchronization as the signal drifts due to noise or other factors. Locking onto a PRBS is fundamental to enabling accurate, efficient, and reliable communication in systems that rely on PRBS-based signaling.

Correlation-based methods for locking onto a PRBS rely on the strong autocorrelation properties of PRBS sequences. These methods enable synchronization between the transmitted PRBS and a locally generated replica at the receiver. Some correlation-based methods are complex and expensive to implement. However, some simpler correlation-based methods do not work well in noisy channels.

### BRIEF DESCRIPTION OF DRAWINGS

Various embodiments in accordance with the present disclosure will be described with reference to the drawings, in which:

FIG. 1 illustrates an example communication system with an error correction circuit according to at least one embodiment.

FIG. 2 is a block diagram of an error correction circuit that performs error correction on an incoming PRBS to generate a corrected PRBS according to at least one embodiment.

FIG. 3 illustrates an example PRBS generator circuit to generate a PRBS of four bits (PRBS4) according to at least one embodiment.

FIG. 4 illustrates multiple stages of an original sequence as it passes through one of the branches of the error correction circuit according to at least one embodiment.

FIG. 5 illustrates multiple stages of an original sequence 502 with an error as it passes through one of the branches of the error correction circuit according to at least one embodiment.

FIG. 6 illustrates an example Gold code generator circuit to generate a Gold code according to at least one embodiment.

FIG. 7 is a block diagram of an error correction circuit that performs error correction on an incoming Gold code sequence according to at least one embodiment.

FIG. 8 is a flow diagram of an example method for correcting errors in an incoming PRBS according to at least one embodiment.

FIG. 9 is a flow diagram of an example method for correcting errors in an incoming Gold code sequence according to at least one embodiment.

FIG. 10 illustrates an example computer system including a spectrum hardware engine and an error correction block according to at least one embodiment.

FIG. 11 is a block diagram of a computing system having two processing devices coupled to each other and multiple networks according to at least one embodiment.

FIG. 12 is a block diagram of a computing system having a central processing unit (CPU) and a graphics processing unit (GPU) in a single integrated circuit according to at least one embodiment.

FIG. 13 is a block diagram of a computing system having tensor core graphics processing units (GPUs) according to at least one embodiment.

### DETAILED DESCRIPTION

Technologies for providing pseudo-random sequence (PRS) error correction in a noisy channel are described. The following description sets forth numerous specific details, such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or presented in simple block diagram format to avoid obscuring the present disclosure unnecessarily. Thus, the specific details set forth are merely exemplary. Particular implementations may vary from these exemplary details and still be contemplated to be within the scope of the present disclosure.

As described above, some correlation-based methods are complex and expensive to implement, and some simpler correlation-based methods do not work well in noisy channels. For example, when a high error rate is expected, an expensive detector is needed to correct errors.

Aspects and embodiments of the present disclosure address these problems and others by providing PRS error correction. Aspects and embodiments of the present disclosure perform error correction on a pseudo-random binary sequence (PRBS), a Gold code sequence (Gold code), or the like.

In general, PRBSs are deterministic binary sequences of 0s and 1s that statistically mimic random behavior. They are extensively used in telecommunications, signal processing, and electronics for transmission and reception, testing, simulation, and system characterization. These sequences are typically generated using Linear Feedback Shift Registers (LFSRs), which make them deterministic while maintaining pseudo-random statistical properties. For an-bit LFSR, by choosing the right polynomial, the sequence cycle is 2ⁿ−1 before repeating, making them maximal-length sequences (MLS) (also referred to as m-sequences). Over a full sequence, the number of 1s and 0s differ by 1, demonstrating balanced properties. Additionally, PRBS sequences adhere to specific run-length constraints, containing all possible patterns of consecutive 1s and 0s of a given length, and their autocorrelation approximates a delta function, making them particularly useful for identifying system responses. Another feature of PRBS sequences is their shift invariance, meaning any shifted version remains a valid sequence within the same period.

In at least one embodiment, a receiver device includes an error correction circuit to receive an incoming PRBS. The incoming PRBS includes an error at a specific bit position. The error correction circuit can generate a plurality of PRBSs using the incoming PRBS and delayed versions of the incoming PRBS, each delayed version being delayed by a different amount such that each of the plurality of PRBSs comprises errors at different bit positions than the specific bit position. The error correction circuit can generate a corrected PRBS using the incoming PRBS and the plurality of PRBSs.

In general, Gold code sequences (also referred to as “Gold codes”) are a type of binary sequence widely used in communication systems, particularly in applications like Global Positioning System (GPS), Code Division Multiple Access(CDMA), and other spread-spectrum technologies. They are valued for their excellent autocorrelation and cross-correlation properties, which make them highly effective in multi-user communication environments. Gold codes are generated by combining two maximal-length sequences (m-sequences) of the same length, typically produced using LFSRs. To create Gold codes, the two m-sequences must be derived from primitive polynomials and maintain a specific fixed shift relative to one another. The resulting codes have a period of N=2ⁿ−1, where is the number of stages in the LFSR, and the set includes 2ⁿ+1 sequences, comprising the original m-sequences and their XORed combinations. In particular, to generate Gold codes, two m-sequences of length N=2ⁿ−1 are produced from LFSRs. These sequences are then combined using the XOR operation with different phase shifts to form a set of codes with desirable correlation properties. The balance between sequence length, size of the code set, and correlation properties makes Gold codes indispensable in modern digital communication systems. Gold codes exhibit balance properties similar to m-sequences, with an equal number of 1s and 0s differing by at most one bit over a full period. Their correlation properties are particularly noteworthy: they have low cross-correlation between different sequences, enabling effective signal separation in multi-user systems, and good autocorrelation, with sharp peaks at zero delay and low values elsewhere, aiding in synchronization and signal detection. These features make Gold codes ideal for applications that demand robust and interference-resistant communication.

In at least one embodiment, a receiver device includes an error correction circuit to receive an incoming Gold code sequence. The incoming Gold code sequence includes an error at a specific bit position. The error correction circuit can generate a plurality of Gold code sequences using the incoming Gold code sequence and delayed versions of the incoming Gold code sequence, each delayed version being delayed by a different amount such that each of the plurality of Gold code sequences comprises errors at different bit positions than the specific bit position. The error correction circuit can generate a corrected Gold code sequence using the plurality of Gold code sequences.

Aspects and embodiments of the present disclosure can be used in any communication link that uses PRS (e.g., PRBS, Gold code, etc.) for synchronization and/or detection. The communication link can be a Serializer-Deserializer (SerDes) link, an NVLink, cellular networking, PCIe, Ethernet, InfiniBand, Ground Reference Signal (GRS), Chip-to-Chip (C2C), Die-to-Die (D2D), LPI (low power interface) or LLI (low latency interface), or the like.

Aspects and embodiments of the present disclosure can be used in various applications, including communication applications with spread-spectrum techniques (e.g., DSSS, CDMA) and channel coding, testing and diagnostic applications (i.e., simulating noise for error rate testing or system calibration), cryptography applications (i.e., generating keys or stream ciphers, radar and sonar applications (i.e., improving signal resolution and reducing ambiguity).

PRS are generated using algorithms or hardware like LFSRs. Despite being deterministic, they appear statistically random over their periods. PRS exhibit properties like sharp autocorrelation peaks and controlled cross-correlation values, which are essential for synchronization, multi-user communication, and interference rejection. These sequences repeat after a specific period, such as N=2ⁿ−1 for maximal-length sequences (m-sequences).

PRBS sequences find applications in various fields. In telecommunications, they simulate random data for testing bit error rates (BER) and are commonly used to evaluate the performance of data links and modems. In electronics testing, they serve as test signals for systems like digital circuits, analog-to-digital converters (ADCs), digital-to-analog converters (DACs), and communication channels, helping analyze noise and interference. Additionally, PRBS sequences are invaluable for system identification, where they excite systems to facilitate the identification of dynamic models due to their ideal autocorrelation properties. Finally, they play a critical role in error checking and noise testing, where they are inserted into channels to evaluate their capacity to handle random noise and distortion.

Other examples of PRS includes PRBS, Gold codes, Kasami sequences, or the like. M-sequences are the basis for many PRSs, including PRBS and Gold codes. M-sequences are generated using primitive polynomials in LFSRs. Gold codes are derived from XOR combinations of two m-sequences with specific relative shifts. Kasami Sequences are a subset of m-sequences with better cross-correlation properties than Gold codes. Kasami Sequences are often used in spread-spectrum systems. Barker Codes are short PRS with near-optimal autocorrelation properties, commonly used in radar and sonar systems. Chaotic Sequences are generated using chaotic systems, providing pseudo-random properties with potential cryptographic applications.

The advantages of Gold codes include strong multi-user support, as their low cross-correlation enables multiple users to share the same frequency spectrum without significant interference. They also provide resistance to narrowband interference in spread-spectrum systems, enhancing signal reliability. Because Gold codes are generated algorithmically, they are deterministic, enabling precise reproduction and synchronization. Additionally, their generation using LFSRs ensures computational efficiency.

Gold codes find diverse applications across communication technologies. In GPS, each satellite uses a unique Gold code to spread its signal, allowing receivers to distinguish between satellites and reduce interference. In CDMA, they are used to assign unique codes to users, enabling simultaneous communication over the same frequency band. They are also used in spread-spectrum communication for spreading narrowband signals across a wider bandwidth, wireless networking for reliable communication in systems like 3G cellular networks, and radar systems to improve signal resolution and reduce ambiguity.

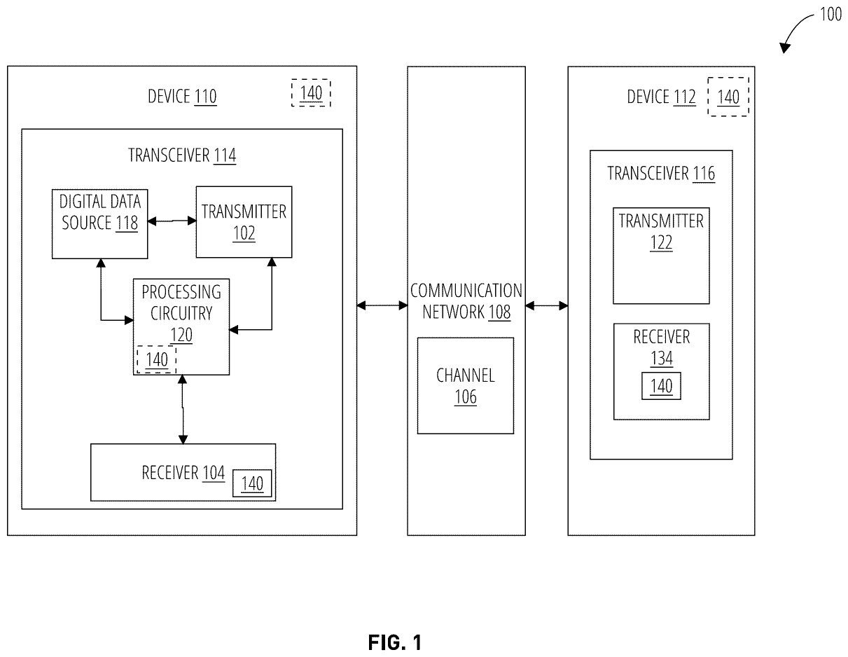

FIG. 1 illustrates an example communication system 100 with an error correction circuit 140, in accordance with at least some embodiments. The communication system 100 includes a device 110, a communication network 108 including a communication channel 106, and a device 112. In at least one example embodiment, devices 110 and 112 correspond to one or more of a Personal Computer (PC), a laptop, a tablet, a smartphone, a server, a collection of servers, or the like. In some embodiments, the devices 110 and 112 may correspond to any appropriate type of device that communicates with other devices also connected to a common type of communication network 108. According to embodiments, the receiver 104 of device 110 or the receiver 134 of device 112 may correspond to a graphics processing unit (GPU), a switch (e.g., a high-speed network switch), a network adapter, a central processing unit (CPU), a data processing unit (DPU), etc. As another specific but non-limiting example, the devices 110 and 112 may correspond to servers offering information resources, services and/or applications to user devices, client devices, or other hosts in the communication system 100.

Examples of the communication network 108 that may be used to connect the devices 110 and 112 include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. In one specific, but non-limiting example, the communication network 108 is a network that enables data transmission between the devices 110 and 112 using data signals (e.g., digital, optical, wireless signals).

The device 110 includes a transceiver 114 for sending and receiving signals, for example, data signals. The data signals may be digital or optical signals modulated with data or other suitable signals for carrying data. The transceiver 114 may include a digital data source 118, a transmitter 102, a receiver 104, and processing circuitry 120 that controls the transceiver 114. The digital data source 118 may include suitable hardware and/or software for outputting data in a digital format (e.g., in binary code and/or thermometer code). The digital data output by the digital data source 118 may be retrieved from memory (not illustrated) or generated according to input (e.g., user input).

The transmitter 102 includes suitable software and/or hardware for receiving digital data from the digital data source 118 and outputting data signals according to the digital data for transmission over the communication network 108 to a receiver 134 of device 112.

The receiver 104 (or receiver 134) may include suitable hardware and/or software for receiving signals, for example, data signals from the communication network 108. For example, the receivers 104 (or receiver 134) may include components for receiving processing signals to extract the data for storing in a memory. In at least one embodiment, the receiver 134 includes an receiver analog front-end circuit (RX AFE circuit) having an error correction circuit 140. In another embodiment, the error correction circuit 140 is part of a digital front-end circuit (RX DFE circuit). In another embodiment, the error correction circuit 140 is implemented in both the analog and digital domains. In other embodiments, the error correction circuit 140 is implemented in other circuits of the device 112 other than the transceiver 116 or receiver 134.

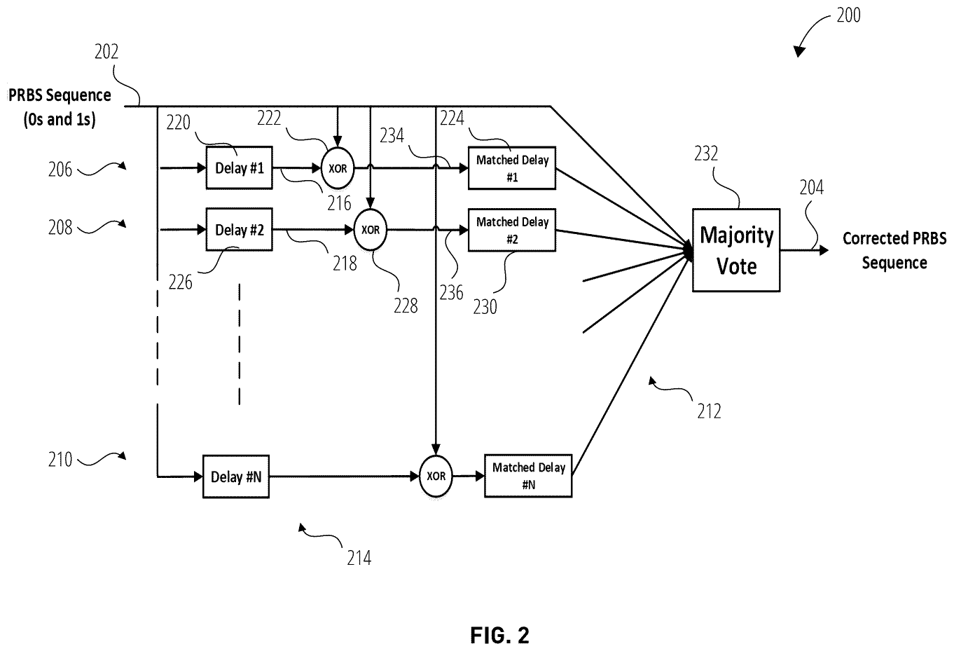

In another embodiment, the receiver 104 also includes an error correction circuit 140. The error correction circuit 140 can be implemented in similar manner as the error correction circuit 140 as described above. The receiver 104 (or receiver 134) receives an incoming signal and samples the incoming signal to generate samples, such as using an analog-to-digital converter (ADC). The RX DFE circuit, including the error correction circuit 140, can be coupled to the ADC. In other embodiments, the error correction circuit 140 can be implemented in the processing circuitry 120 of the respective device. As noted above, the error correction circuit 140 can be implemented in other circuits of the device 110 other than the transceiver 114 or the receiver 104. Additional details of the error correction circuit 140 are discussed in more detail below with respect to FIG. 2.

The processing circuitry 120 may comprise software, hardware, or a combination thereof. For example, the processing circuitry 120 may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory). Additionally or alternatively, the processing circuitry 120 may comprise hardware, such as an application specific integrated circuit (ASIC). Other non-limiting examples of the processing circuitry 120 include an Integrated Circuit (IC) chip, a CPU, a GPU, a DPU, a microprocessor, a Field Programmable Gate Array (FPGA), a collection of logic gates or transistors, resistors, capacitors, inductors, diodes, or the like. Some or all of the processing circuitry 120 may be provided on a Printed Circuit Board (PCB) or collection of PCBs. It should be appreciated that any appropriate type of electrical component or collection of electrical components may be suitable for inclusion in the processing circuitry 120. The processing circuitry 120 may send and/or receive signals to and/or from other elements of the transceiver 114 to control the overall operation of the transceiver 114.

The transceiver 114 or selected elements of the transceiver 114 may take the form of a pluggable card or controller for the device 110. For example, the transceiver 114 or selected elements of the transceiver 114 may be implemented on a network interface card (NIC).

The device 112 may include a transceiver 116 for sending and receiving signals, for example, data signals over a channel 106 of the communication network 108. The same or similar structure of the transceiver 114 may be applied to transceiver 116, and thus, the structure of transceiver 116 is not described separately. The channel 106 can be PCIe, NVLink, Ethernet, InfiniBand, Ground Reference Signal (GRS), Chip-to-Chip (C2C), Die-to-Die (D2D), LPI (low power interface) or LLI (low latency interface), or the like. The same or similar structure of the transceiver 114 may be applied to transceiver 116, and thus, the structure of transceiver 116 is not described separately.

Although not explicitly shown, it should be appreciated that devices 110 and 112 and the transceivers 114 and 116 may include other processing devices, storage devices, and/or communication interfaces generally associated with computing tasks, such as sending and receiving data.

In at least one embodiment, the error correction circuit 140 can receive an incoming PRBS. The incoming PRBS includes an error at a specific bit position. The error correction circuit 140 can generate a plurality of PRBSs using the incoming PRBS and delayed versions of the incoming PRBS, each delayed version being delayed by a different amount such that each of the plurality of PRBSs includes errors at different bit positions than the specific bit position. The error correction circuit 140 can generate a corrected PRBS using the incoming PRBS and the plurality of PRBSs. Additional details of the error correction circuit 140 that can receive an incoming PRBS are described below with respect to FIG. 2 to FIG. 5.

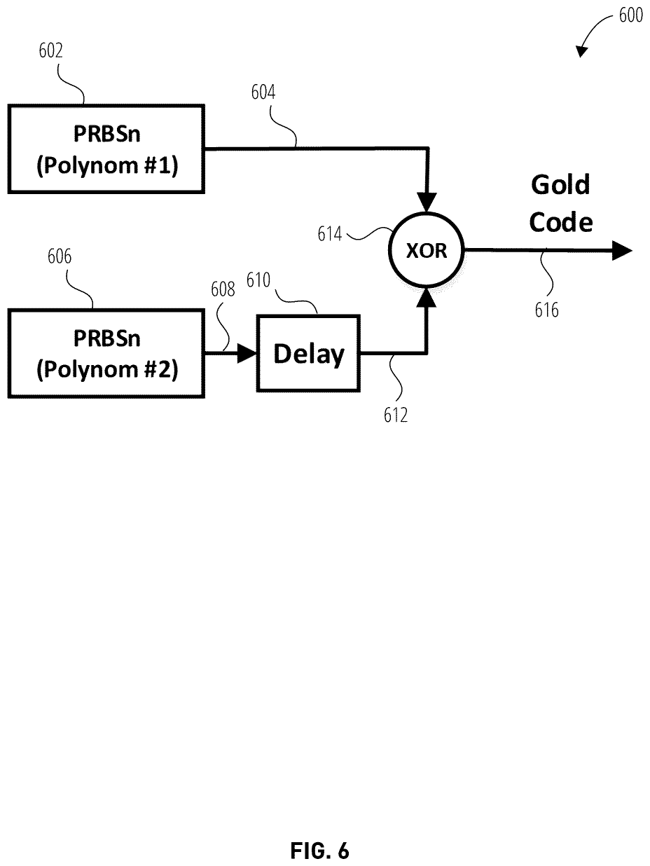

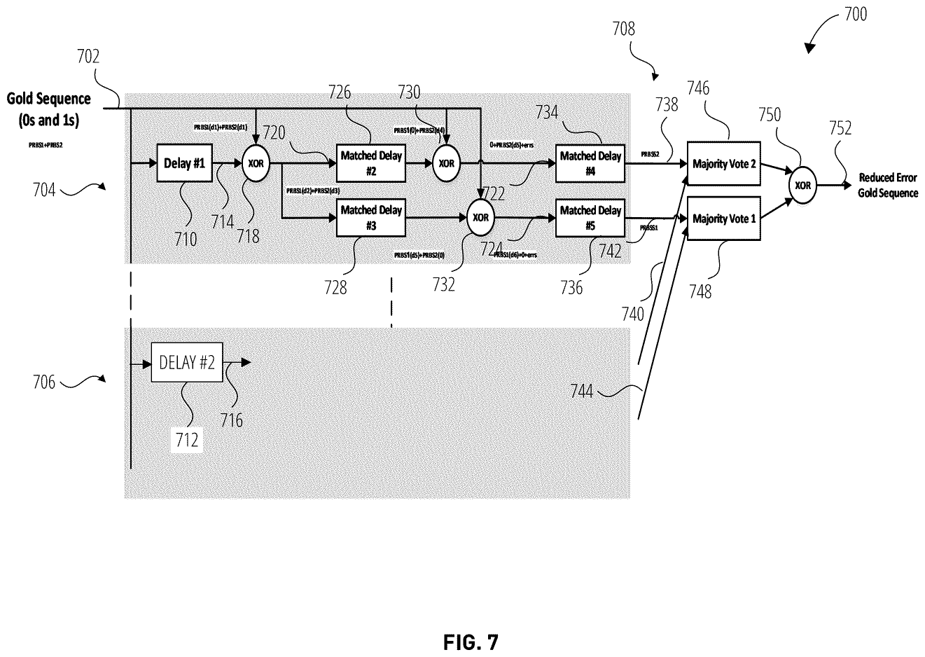

In at least one embodiment, the error correction circuit 140 can receive an incoming Gold code sequence. The incoming Gold code sequence includes an error at a specific bit position. The error correction circuit 140 can generate a plurality of Gold code sequences using the incoming Gold code sequence and delayed versions of the incoming Gold code sequence, each delayed version being delayed by a different amount such that each of the plurality of Gold code sequences includes errors at different bit positions than the specific bit position, and generate a corrected Gold code sequence using the plurality of Gold code sequences. Additional details of the error correction circuit 140 that can receive an incoming Gold code sequence are described below with respect to FIG. 6 to FIG. 7.

FIG. 2 is a block diagram of an error correction circuit 200 that performs error correction on an incoming PRBS 202 to generate a corrected PRBS 204 according to at least one embodiment. The error correction circuit 200 can be the error correction circuit 140 of FIG. 1. As described above, the error correction circuit 200 can receive the incoming PRBS 202. In at least one embodiment, the incoming PRBS 202 can be generated using feedback-based methods, particularly LFSRs. In this process, a register shifts bits sequentially, with the feedback determined by specific positions (taps) defined by a primitive polynomial. This efficient mechanism allows for reproducibility and precise control over the sequence properties. The incoming PRBS 202 includes an error at a specific bit position. The error correction circuit 200 can include N number of branches to generate multiple PRBSs 212 using the incoming PRBS 202 and Delayed versions 214 of the incoming PRBS 202. Each delayed version 214 is delayed by a different amount such that each of the multiple PRBSs 212 includes errors at different bit positions than the specific bit position. The error correction circuit 200 can generate a corrected PRBS 204 using the incoming PRBS 202 and the multiple PRBSs 212. In at least one embodiment, the corrected PRBS 204 is generated using a majority vote decision 232, as illustrated in FIG. 2.

As illustrated in FIG. 2, the N number of branches includes a first branch 206, a second branch 208, and a Nth branch 210. N can be 2 or greater. To generate the multiple PRBSs 212, the first branch 206 can generate a first delayed version 216 of the incoming PRBS 202 using a first delay element 220, and the second branch 208 can generate second delayed version 218 of the incoming PRBS 202 using a second delay element 226. A first delay amount associated with the first delayed version 216 is different than a second delay amount associated with the second delayed version 218. That is, the first delay element 220 can delay the incoming PRBS 202 by the first delay amount, and the second delay element 226 can delay the incoming PRBS 202 by the second delay amount, the second delay amount being different than the first delay amount. Similarly, if there are additional branches, each branch can generate a delayed version of the incoming PRBS 202 using its respective delay element.

Each of the N branches can perform an exclusive OR operation (XOR operation) of the incoming PRBS 202 and the respective delayed version. As illustrated, the first branch 206 performs a first XOR operation 222 of the incoming PRBS 202 and the first delayed version 216 to obtain a first result 234, and the second branch 208 performs a second XOR operation 228 of the incoming PRBS 202 and the second delayed version 218 to obtain a second result 236. Similarly, if there are additional branches, each branch can perform an XOR operation of the incoming PRBS 202 and the respective delayed version to obtain a corresponding result.

As illustrated and described below in more detail, the results need to be synchronized with the incoming PRBS 202. This can be done using additional delay elements, called matched delay elements to differentiate these delay elements from the delay elements used to generate the delayed versions 214. These matched delay elements can have different delay amounts that are set to align or synchronize the respective result with the incoming PRBS 202. As illustrated, the first branch 206 synchronizes the first result 234 with the incoming PRBS 202 by delaying the first result 234 by a third delay amount to obtain a first PRBS of the multiple PRBSs 212, and the second branch 208 synchronizes the second result 236 with the incoming PRBS 202 by delaying the second result 236 by a fourth delay amount to obtain a second PRBS of the multiple PRBSs 212. Similarly, if there are additional branches, each branch can match delay the respective result with the incoming PRBS 202 using its respective matched delay element.

Once the results are synchronized, the error correction circuit 200 can generate the corrected PRBS 204 using the incoming PRBS 202 and the multiple PRBSs 212. For example, when there are two branches, the error correction circuit 200 can generate corrected PRBS 204 using the incoming PRBS 202, the first PRBS, and the second PRBS.

In at least one embodiment, the error correction circuit 200 can generate the corrected PRBS 204 by making a majority vote decision 232 for each bit in the corrected PRBS 204 using the corresponding bits in the multiple PRBSs 212 and the incoming PRBS 202. For example, the majority vote decision 232 can be performed on each bit in the first PRBS, the second PRBS, and the incoming PRBS 202 when there are two branches.

In at least one embodiment, the error correction circuit 200 can generate the corrected PRBS 204 by making a weighted vote decision for each bit in the corrected PRBS 204 using the corresponding bits in the multiple PRBSs 212 and the incoming PRBS 202. For example, the weighted vote decision can be performed on each bit in the first PRBS, the second PRBS, and the incoming PRBS 202 when there are two branches.

In at least one embodiment, the error correction circuit 200 can generate the corrected PRBS 204 by making a plurality vote decision for each bit in the corrected PRBS 204 using the corresponding bits in the multiple PRBSs 212 and the incoming PRBS 202. For example, the plurality vote decision can be performed on each bit in the first PRBS, the second PRBS, and the incoming PRBS 202 when there are two branches.

In at least one embodiment, where N is equal to 3, the error correction circuit 200 can generate a third delayed version of the incoming PRBS 202. A fifth delay amount associated with the third delayed version is different than the second delay amount associated with the second delayed version. The error correction circuit 200 can perform a third XOR operation of the incoming PRBS and the third delayed version to obtain a third result, and synchronize the third result with the incoming PRBS 202 by delaying the third result by a sixth delay amount to obtain a third PRBS of the multiple PRBSs 212. The corrected PRBS can be generated using the incoming PRBS 202, the first PRBS, the second PRBS, and the third PRBS.

In at least one embodiment, the receiver device includes physical layer logic to receive a PRBS over a channel, and datalink layer logic coupled to the physical layer logic. The datalink layer logic can generate a first delayed version of the PRBS and a second delayed version of the PRBS. A first delay amount associated with the first delayed version is different than a second delay amount associated with the second delayed version. The datalink layer logic can perform a first exclusive OR (XOR) operation of the PRBS and the first delayed version to obtain a first result. The datalink layer logic can perform a second XOR operation of the PRBS and the second delayed version to obtain a second result. The datalink layer logic can synchronize the first result and the second result with the PRBS by delaying the first result by a third delay amount and the second result by a fourth delay amount. The datalink layer logic can generate, using the first result, the second result, and the PRBS, a corrected PRBS. In a further embodiment, the PRBS is generated by a n-bit LFSR and has a sequence cycle of 2ⁿ−1, where n is a positive integer greater than one. The PRBS includes an error at a specific bit position. After synchronized with the PRBS, the first result includes up to two errors at different bit positions than the specific bit position, the second result comprises up to two errors at different bit positions than the specific bit position, and the specific bit position of the first result and the second result do not comprise the error. In at least one embodiment, the n is four, five, thirteen, thirty one, or the like.

In at least one embodiment, the datalink layer logic can make a majority vote decision for each bit on the first result, the second result, and the PRBS to generate the corrected PRBS. In at least one embodiment, the datalink layer logic can make a weighted vote decision on the first result, the second result, and the PRBS to generate the corrected PRBS. In at least one embodiment, the datalink layer logic can make a plurality vote decision on the first result, the second result, and the PRBS to generate the corrected PRBS.

In at least one embodiment, the datalink layer logic can generate a third delayed version of the PRBS. A fifth delay amount associated with the third delayed version is different than the second delay amount associated with the second delayed version. The datalink layer logic can perform a third XOR operation of the PRBS and the third delayed version to obtain a third result. The datalink layer logic can synchronize the third result with the PRBS by delaying the third result by a sixth delay amount. The corrected PRBS is generated using the first result, the second result, the third result, and the PRBS.

In at least one embodiment, the receiver device includes an analog-to-digital converter (ADC) to sample an incoming signal to obtain data samples, including the 0s and 1s of the incoming signal.

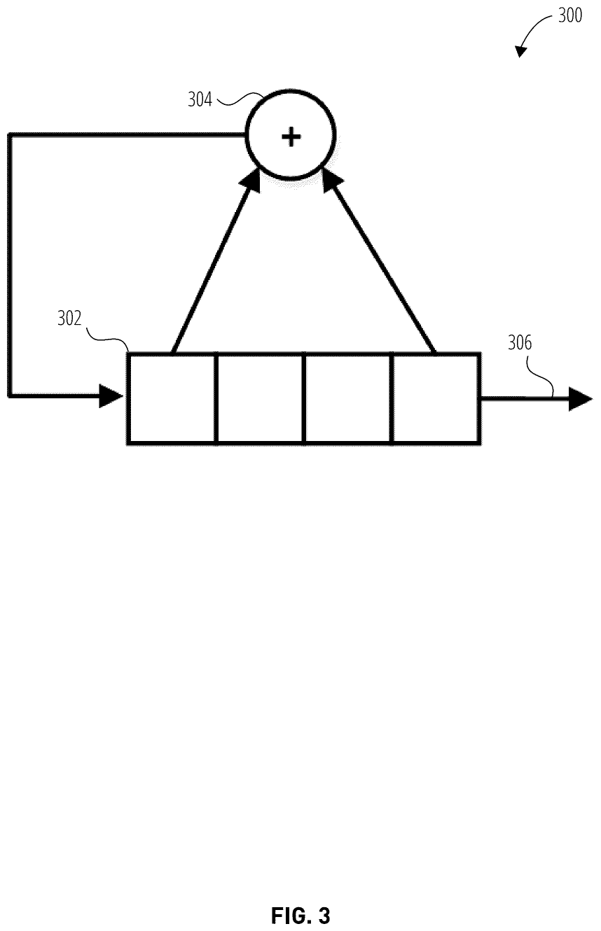

As described above, the incoming PRBS 202 is a deterministic binary sequences of 0s and 1s that statistically mimic random behavior. In at least one embodiment, the incoming PRBS 202 is generated using an-bit LFSR, and the incoming PRBS 202 can have a sequence cycle of N=2ⁿ−1 before repeating. The incoming PRBS 202 can be balanced. That is, over a full sequence, the number of 1s and 0s differ by at most 1. Additionally, the incoming PRBS 202 can have a specific run-length constraint, containing all possible patterns of consecutive 1s and 0s of a given length, and their autocorrelation approximates a delta function, making them particularly useful for identifying system responses. Most importantly here, any shifted version of the incoming PRBS 202 remains a valid sequence within the same period. Additional details of generating the multiple PRBSs 212 using synchronized delayed versions 214 are described below with respect to FIG. 3 to FIG. 5.

FIG. 3 illustrates an example PRBS generator circuit 300 to generate a PRBS of four bits (PRBS4) according to at least one embodiment. The PRBS generator circuit 300 includes an LSFR 302 with four stages (e.g., flip-flops) and an XOR gate 304. The four flip-flops are connected in series to form a shift register. These form the 4-stage shift register can hold the state of the sequence. The XOR gate 304 provides feedback to create the pseudo-random behavior. The flip-flops of the LSFR 302 can be driving by a clock source to shift the bits at each clock cycle. The output of specific stages of the shift register (as determined by the feedback taps) is fed into the XOR gate 304 The XOR gate's output is fed back to the input of the first flip-flop (the feedback mechanism) of the LSFR 302. For a PRBS4 sequence, the feedback taps are chosen based on the primitive polynomial x⁴+x+1. The output of any stage (commonly the last stage) provides the PRBS4 sequence 306.

It should be noted that the LSFR 302 is initialized to a non-zero state (e.g., 0001) to avoid a state of all zeros is avoided, as it would lock the LFSR in a non-varying state. The maximal length (also referred to as the sequence cycle) of the PRBS4 sequence 306 is 15 (2⁴−1=15), as the primitive polynomial ensures all states except all zeros are used. The sequence length is 15, meaning the PRBS4 sequence 306 will generate 15 unique states before repeating. The PRBS4 sequence 306 appears random but is deterministic based on the initial state and feedback taps. In other embodiments, any stage of the LSFR 302 can be used as the output. In other embodiments, other sizes of PRBS can be used, such as PRBS−N, where N is the length of the LSFR 302, and the sequence cycle is expressed as 2^{N}−1. The PRBS generator circuit 300 can be used in communication systems for synchronization, delay measurements, etc. If the bit error rate (BER) is low, the synchronization is very fast and low-cost. If the BER is high, the synchronization is slow and expensive using the conventional solutions. The embodiments described herein reduce the BER using the characteristics of the PRBS instead of using the expensive solutions.

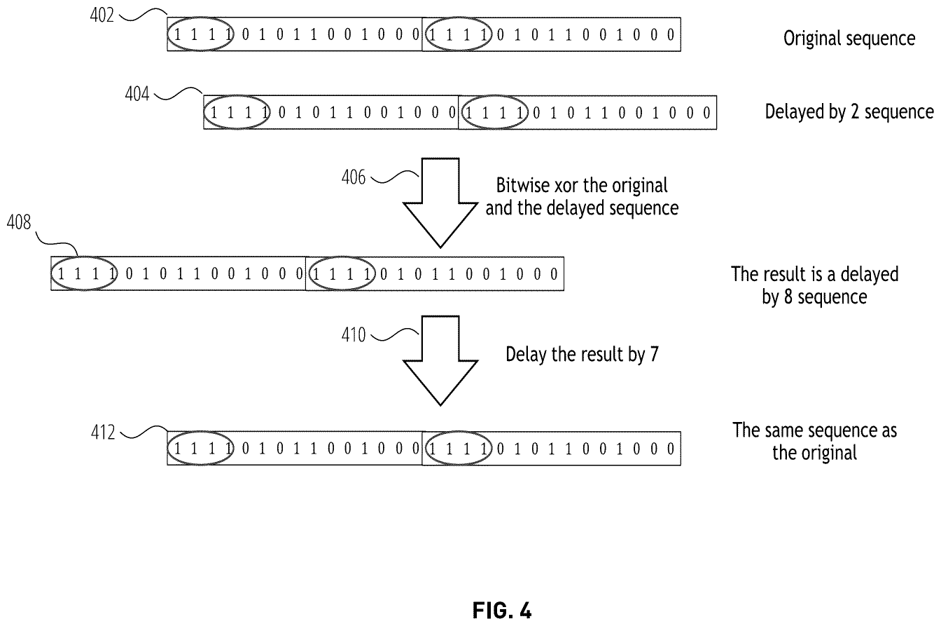

The PRBS generator circuit 300 can be used to generate an original sequence (PRBS) having a specified cycle length. This sequence and delayed versions of the sequence can be passed through different branches of the error correction circuit to generate a corrected sequence, as illustrated and described below with respect to FIG. 4.

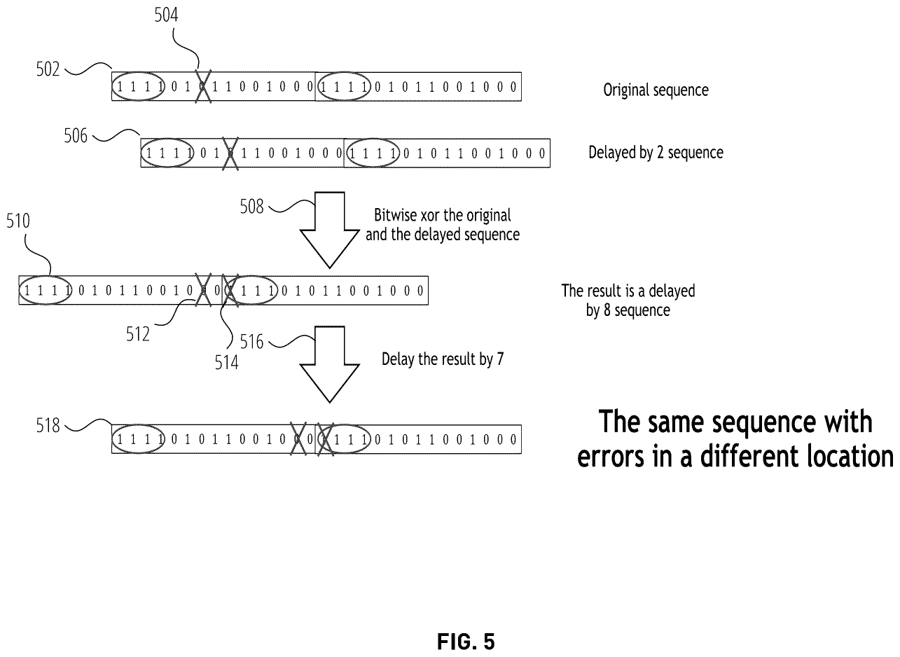

FIG. 4 illustrates multiple stages of an original sequence 402 as it passes through one of the branches of the error correction circuit according to at least one embodiment. One stage of the error correction circuit receives the original sequence 402. As illustrated in FIG. 4, the original sequence 402 has a sequence cycle of 15, as shown by the state of 1011 is repeated after fifteen bits. The stage can include a delay element to delay the original sequence 402 to obtain a delayed version 404. In this example, the original sequence 402 is delayed by 2 bits to obtain the delayed version 404. The stage then performs an XOR operation 406 of the original sequence 402 and the delayed version 404 to obtain a result 408. The result is a delayed version by 8 sequences. As such, the stage then performs a matched delay operation 410 to delay the result by 7 to obtain a delayed version 412 that is the same sequence as the original sequence 402. In this example, there is an assumption that there are not errors in the sequence. When the original sequence 402 has errors, the delayed version 412 is the same sequence but with the errors in a different location, as illustrated and described below with respect to FIG. 5.

FIG. 5 illustrates multiple stages of an original sequence 502 with an error 504 as it passes through one of the branches of the error correction circuit according to at least one embodiment. One stage of the error correction circuit receives the original sequence 502. As illustrated in FIG. 5, the original sequence 502 is similar to the original sequence 402, except the original sequence 502 includes the error 504 at a specified bit position (e.g., 7th bit). The stage can include a delay element to delay the original sequence 502 to obtain a delayed version 506. In this example, the original sequence 502 is delayed by 2 bits to obtain the delayed version 506. The delayed version 506 includes the error at the same bit position. The stage then performs an XOR operation 508 of the original sequence 502 and the delayed version 506 to obtain a result 510. The result 510 is a delayed version by 8 sequences. The result 510 however has two errors 512 and 514 at different bit positions than the error 504. It should be noted that for each error in the original sequence 502, there can be up to two errors at different bit positions in the results since sometimes there can be two errors at the same location that cancel each other out to be no error. The stage then performs a matched delay operation 516 to delay the result by 7 to obtain a delayed version 518 that is the same sequence as the original sequence 502, except the errors 512 and 514 are in different bit positions than the error 504 in the original sequence 502. The error correction circuit can use the original sequence 502 and the delayed version 518 to make a decision on what each bit of the original sequence 502 should be to correct for the error 504.

The error correction circuit can generate multiple sequences, where the sequences in each branch are equal and synchronized with errors in different locations. The error correction circuit can make a decision for each bit, such as a majority vote decision. For example, the error correction circuit can use a majority vote decision on each bit of the sequence using at least two delayed versions with errors in different bit positions and the original sequence 502 with the error 504 to obtain a corrected sequence. The corrected sequence will be the same as the original sequence 502, except without the error 504.

As described above, Gold codes are commonly used in communication systems, such as GPS, CDMA, etc. Gold codes have very good cross correlation properties and are easy to generate in hardware or software. Similarly, delayed versions of a Gold code sequence can be used to correct errors in an original Gold Code sequence as described below with respect to FIG. 6 to FIG. 7.

FIG. 6 illustrates an example Gold code generator circuit to generate a Gold code according to at least one embodiment. The Gold code generator circuit 600 includes a first primitive polynomial 602 to generate a first PRBS 604, and a second primitive polynomial 606 to generate a second PRBS 608. Each polynomial pair of PRBS generate a family of 2^{N}−1 codes. A very good cross-correlation exists among the codes in a family. Each delay can generate a new Gold code in the family. As illustrated in FIG. 6, the Gold code generator circuit 600 includes a delay element 610 that delays the second PRBS 608 by a specified amount to obtain a delayed PRBS 612. The delay amount can be any number (0.2^{N}-2). Each delay generates a new The Gold code generator circuit 600 performs an XOR operation 614 on the first PRBS 604 and the delayed PRBS 612 to obtain a Gold code 616.

The Gold code generator circuit 600 can be used to generate an original Gold sequence of 0s and 1s. This Gold sequence can be passed through different branches of an error correction circuit to generate a corrected Gold sequence, as illustrated and described below with respect to FIG. 7.

FIG. 7 is a block diagram of an error correction circuit 700 that performs error correction on an incoming Gold code sequence 702 according to at least one embodiment. The error correction circuit 700 can be the error correction circuit 140 of FIG. 1. In at least one embodiment, the incoming Gold code sequence 702 can be generated using the Gold code generator circuit 600 of FIG. 6. The incoming Gold code sequence 702 can include an error at a specific bit position. The error correction circuit 700 can include N number of branches to generate multiple PRBSs 708, two PRBSs per branch, using the incoming Gold code sequence 702. Each of the multiple PRBSs 708 are delayed by a different amount such that each of the multiple PRBSs 708 includes errors at different bit positions than the specific bit position. The error correction circuit 700 can generate a corrected Gold code sequence 752 using the multiple PRBSs 708. In at least one embodiment, the corrected Gold code sequence 752 is generated using majority vote decisions 746, majority vote decision 748, etc., as illustrated in FIG. 7.

As illustrated in FIG. 7, the N number of branches includes a first branch 704 and a second branch 706, but can include additional branches. To generate the multiple PRBSs 708, the first branch 704 can generate two PRBSs, including a first PRBS 738 and a third PRBS 742, using a first delay element 710, a first XOR operation 718, second XOR operation 730, third XOR operation 732, and matched delay elements as described in more detail below. The second branch 706 can generate two PRBSs, including a second PRBS 740 and a fourth PRBS 744 using a second delay element 712 and similar XOR operations and respective matched delay elements. A first delay amount associated with a first delayed version 714 of the incoming Gold code sequence 702 is different than a second delay amount associated with a second delayed version 716. That is, the first delay element 710 can delay the incoming Gold code sequence 702 by the first delay amount, and the second delay element 712 can delay the incoming Gold code sequence 702 by the second delay amount, the second delay amount being different than the first delay amount. Similarly, if there are additional branches, each branch can generate a delayed version of the incoming Gold code sequence 702 using its respective delay element.

Each of the N branches can perform an exclusive OR operation (XOR operation) of the incoming Gold code sequence 702 and the respective delayed version. As illustrated, the first branch 704 performs a first XOR operation 718 of the incoming Gold code sequence 702 and the first delayed version 714 to obtain a first result 720. The first result 720 can be delayed by two different matched delay elements and XOR'd to remove on the PRBS in the sequence. In particular, a first matched delay element 726 receives the first result 720 to delay the first result 720 by a second delay amount, and a second matched delay element 728 receives the first result 720 to delay the first result 720 by a third delay amount that is different than the second delay amount. A second XOR operation 730 and third XOR operation 732 are performed on the incoming Gold code sequence 702 and the corresponding delayed versions of the first result 234 to obtain a third result 722 and a fourth result 724, respectively.

Similarly, the second branch 706 performs a second XOR operation of the incoming Gold code sequence 702 and the second delayed version 716 to obtain a result. The result can similarly be delayed by two different amounts and XOR'd to obtain a fifth result and a second result. Similarly, if there are additional branches, each branch can perform an XOR operation of the incoming PRBS 202 and the respective delayed version to obtain a corresponding result.

As illustrated and described below in more detail, the results need to be synchronized with each other. This can be done using additional matched delay elements, such as illustrated by a third matched delay element 734 and a fourth matched delay element 736. These matched delay elements can have different delay amounts that are set to align or synchronize the respective result with each other. As illustrated, the first branch 704 synchronizes the third result 722 and the fourth result 724 by delaying the third result 722 by a delay amount to obtain a first PRBS 738 and delaying the fourth result 724 by a delay amount to obtain a second PRBS 740. Similarly, the second branch 706 synchronizes a corresponding fifth and sixth results to obtain a second PRBS 740 and a fourth PRBS 744, respectively. Similarly, if there are additional branches, each branch can match delay the respective result with the other results using its respective matched delay element.

Once the results are synchronized, the error correction circuit 700 can generate the corrected Gold code sequence 752 by making a majority vote decision for each bit using the corresponding bits in corresponding PRBSs from each of the branches. For example, a first majority vote decision 746 is performed on the first PRBS 738 from the first branch 704 and the second PRBS 740 from the second branch 706. A majority vote decision 748 is performed on the third PRBS 742 from the first branch 704 and the fourth PRBS 744 from the second branch 706. The result of the majority vote decision 746 and the majority vote decision 748 is XOR'd using a fourth XOR operation 750 to obtain the corresponding bit in the corrected Gold code sequence 752. It should be noted that since the incoming Gold code sequence is separated into two PRBSs, only the PRBSs are used in the voting decisions, unlike the voting decisions in FIG. 2 that use the incoming PRBS as well.

In at least one embodiment, the error correction circuit 700 can generate the corrected Gold code sequence 752 by making a weighted vote decision for each bit in the corrected Gold code sequence 752. In at least one embodiment, the error correction circuit 700 can generate the corrected Gold code sequence 752 by making a plurality vote decision for each bit in the corrected Gold code sequence 752.

In at least one embodiment, the receiver device includes physical layer logic to receive a Gold code sequence over a channel and datalink layer logic coupled to the physical layer logic. The datalink layer logic can perform the various operations of the error correction circuit 700 described above. In at least one embodiment, a receiver device includes physical layer logic to receive a Gold code sequence over a channel, and datalink layer logic coupled to the physical layer logic. The datalink layer logic can perform a first exclusive OR (XOR) operation of the incoming Gold code sequence and a first delayed version of the incoming Gold code sequence to obtain a first result. The datalink layer logic can perform a second XOR operation of the incoming Gold code sequences and a second delayed version of the incoming Gold code sequence to obtain a second result. A first delay amount associated with the first delayed version of the incoming Gold code sequence is different than a second delay amount associated with the second delayed version of the incoming Gold code sequence. The datalink layer logic can generate and synchronize a third result and a fourth result using the first result. The datalink layer logic can generate and synchronize a fifth result and a sixth result using the second result. The datalink layer logic can make a first majority vote decision using the third result and the fifth result. The datalink layer logic can make a second majority vote decision using the fourth result and the sixth result. The datalink layer logic can perform a third XOR operation of the first majority vote decision and the second majority vote decision to generate a corrected Gold code sequence.

In a further embodiment, the datalink layer logic can perform a fourth XOR operation of a first delayed version of the first result and the incoming Gold code sequence to generate the third result. The datalink layer logic can perform a fifth XOR operation of a second delayed version of the first result and the incoming Gold code sequence to generate the fourth result. The datalink layer logic can perform a sixth XOR operation of a first delayed version of the second result and the incoming Gold code sequence to generate the fifth result. The datalink layer logic can perform a seventh XOR operation of a second delayed version of the second result and the incoming Gold code sequence to generate the sixth result.

In a further embodiment, a third delay amount associated with the first delayed version of the first result is different than a fourth delay amount associated with the second delayed version of the first result. In at least one embodiment, a fifth delay associated with the first delayed version of the second result is different than a sixth delay amount associated with the second delayed version of the second result.

In a further embodiment, the datalink layer logic can synchronize a third result and a fourth result by delaying the third result by a third delay amount and delaying the fourth result by a fourth delay amount. The datalink layer logic can synchronize the fifth result and the sixth result by delaying the fifth result by a fifth delay amount and the sixth result by a sixth delay amount.

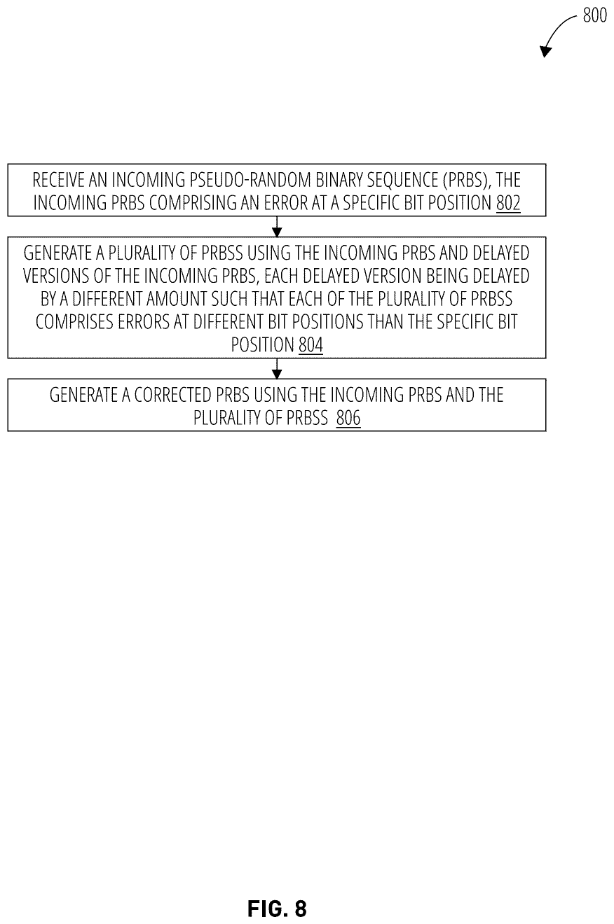

FIG. 8 is a flow diagram of an example method 800 for correcting errors in an incoming PRBS according to at least one embodiment. Method 800 can be performed using one or more processing units (e.g., CPUs, GPUs, accelerators, physics processing units (PPUs), data processing units (DPUs), etc.), which may include (or communicate with) one or more memory devices. In at least one embodiment, method 800 can be performed using a processing device or processing devices. In at least one embodiment, method 800 can be performed using processing units of component of FIG. 1 (e.g., error correction circuit 140). In at least one embodiment, method 800 can be performed by processing units of a component of FIG. 2 (e.g., error correction circuit 200). In at least one embodiment, the method 800 can be performed by processing units of a component of FIG. 7 (e.g., error correction circuit 700). In at least one embodiment, processing units performing the method 800 can be executing instructions stored on a non-transient computer readable storage media. In at least one embodiment, the method 800 can be performed using multiple processing threads (e.g., CPU threads and/or GPU threads), individual threads executing one or more individual functions, methods, subroutines, or operations of the method. In at least one embodiment, processing threads implementing any of method 800 can be synchronized (e.g., using semaphores, critical sections, and/or other thread synchronization mechanisms). Alternatively, processing threads implementing the method 800 can be executed asynchronously with respect to each other. Various operations of method 800 can be performed in a different order compared with the order shown in FIG. 8. Some operations of the method 800 can be performed concurrently with other operations. In at least one embodiment, one or more operations shown in FIG. 8 may not always be performed.

Referring to FIG. 8, the processing logic begins the method 800 by the processing logic receiving an incoming pseudo-random binary sequence (PRBS) (block 802). The incoming PRBS includes an error at a specific bit position. At block 804, the processing logic generates a plurality of PRBSs using the incoming PRBS and delayed versions of the incoming PRBS. Each delayed version is delayed by a different amount such that each of the plurality of PRBSs comprises errors at different bit positions than the specific bit position. At block 806, the processing logic generates a corrected PRBS using the incoming PRBS and the plurality of PRBSs.

In a further embodiment, at block 804, the processing logic generates the plurality of PRBSs by generating a first delayed version of the incoming PRBS and a second delayed version of the incoming PRBS. A first delay amount associated with the first delayed version is different than a second delay amount associated with the second delayed version. The processing logic performs a first exclusive OR (XOR) operation of the incoming PRBS and the first delayed version to obtain a first result. The processing logic performs a second XOR operation of the incoming PRBS and the second delayed version to obtain a second result. The processing logic synchronizes the first result and the second result with the incoming PRBS by delaying the first result by a third delay amount to obtain a first PRBS of the plurality of PRBSs and the second result by a fourth delay amount to obtain a second PRBS of the plurality of PRBSs. The corrected PRBS is generated using the incoming PRBS, the first PRBS, and the second PRBS. In a further embodiment, at block 802, the processing logic generates the plurality of PRBSs by further generating a third delayed version of the incoming PRBS. A fifth delay amount associated with the third delayed version is different than the second delay amount associated with the second delayed version. The processing logic performs a third XOR operation of the incoming PRBS and the third delayed version to obtain a third result. The processing logic synchronizes the third result with the incoming PRBS by delaying the third result by a sixth delay amount to obtain a third PRBS of the plurality of PRBSs. The corrected PRBS is generated using the incoming PRBS, the first PRBS, the second PRBS, and the third PRBS.

In at least one embodiment, the processing logic makes a majority vote decision for each bit in the corrected PRBS using the corresponding bits in the first PRBS, the second PRBS, and the incoming PRBS. In at least one embodiment, the processing logic makes a weighted vote decision for each bit in the corrected PRBS using the corresponding bits in the first PRBS, the second PRBS, and the incoming PRBS. In at least one embodiment, the processing logic makes a plurality vote decision for each bit in the corrected PRBS using the corresponding bits in the first PRBS, the second PRBS, and the incoming PRBS.

The processing logic can perform other operations as described herein in method 800.

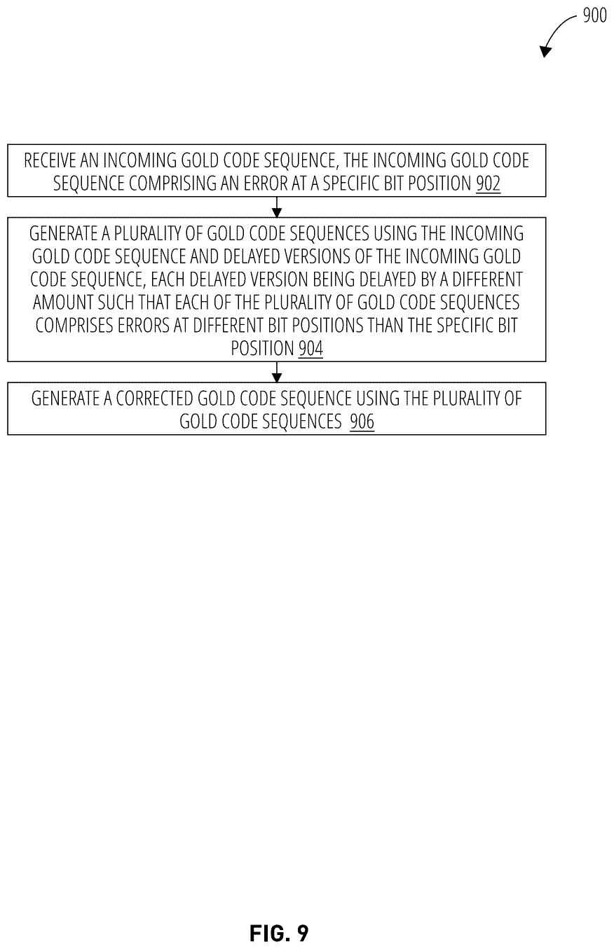

FIG. 9 is a flow diagram of an example method 900 for correcting errors in an incoming Gold code sequence according to at least one embodiment. Method 900 can be performed using one or more processing units (e.g., CPUs, GPUs, accelerators, physics processing units (PPUs), data processing units (DPUs), etc.), which may include (or communicate with) one or more memory devices. In at least one embodiment, method 900 can be performed using a processing device or processing devices. In at least one embodiment, method 900 can be performed using processing units of component of FIG. 1 (e.g., error correction circuit 140). In at least one embodiment, method 900 can be performed by processing units of a component of FIG. 2 (e.g., error correction circuit 200). In at least one embodiment, the method 900 can be performed by processing units of a component of FIG. 7 (e.g., error correction circuit 700). In at least one embodiment, processing units performing the method 900 can be executing instructions stored on a non-transient computer readable storage media. In at least one embodiment, the method 900 can be performed using multiple processing threads (e.g., CPU threads and/or GPU threads), individual threads executing one or more individual functions, methods, subroutines, or operations of the method. In at least one embodiment, processing threads implementing any of method 900 can be synchronized (e.g., using semaphores, critical sections, and/or other thread synchronization mechanisms). Alternatively, processing threads implementing the method 900 can be executed asynchronously with respect to each other. Various operations of method 900 can be performed in a different order compared with the order shown in FIG. 9. Some operations of the method 900 can be performed concurrently with other operations. In at least one embodiment, one or more operations shown in FIG. 9 may not always be performed.

Referring to FIG. 9, the processing logic begins the method 900 by the processing logic receiving an incoming Gold code sequence (block 902), the incoming Gold code sequence comprising an error at a specific bit position. At block 904, the processing logic generates a plurality of Gold code sequences using the incoming Gold code sequence and delayed versions of the incoming Gold code sequence, each delayed version being delayed by a different amount such that each of the plurality of Gold code sequences comprises errors at different bit positions than the specific bit position. At block 906, the processing logic generates a corrected Gold code sequence using the plurality of Gold code sequences.

In at least one embodiment, at block 904, the processing logic generates the plurality of Gold code sequences by perform a first exclusive OR (XOR) operation of the incoming Gold code sequence and a first delayed version of the incoming Gold code sequence to obtain a first result. The processing logic performs a second XOR operation of the incoming Gold code sequence and a second delayed version of the incoming Gold code sequence to obtain a second result. A first delay amount associated with the first delayed version of the incoming Gold code sequence is different than a second delay amount associated with the second delayed version of the incoming Gold code sequence. The processing logic generates and synchronizes a third result and a fourth result using the first result. The processing logic generates and synchronizes a fifth result and a sixth result using the second result.

In at least one embodiment, at block 904, the processing logic generates the corrected Gold code sequence by making a first majority vote decision for each respective bit in the third result and the fifth result, making a second majority vote decision for each respective bit in the fourth result and the sixth result, and performing a third XOR operation of the first majority vote decision and the second majority vote decision for each bit in the corrected Gold code sequence. Similarly, the processing logic can use a weighted vote decision, a plurality vote decision, or the like, instead of a majority vote decision.

In at least one embodiment, at block 904, the processing logic generates the plurality of Gold code sequences by performing a fourth XOR operation of a first delayed version of the first result and the incoming Gold code sequence to generate the third result. The processing logic performs a fifth XOR operation of a second delayed version of the first result and the incoming Gold code sequence to generate the fourth result. The processing logic performs a sixth XOR operation of a first delayed version of the second result and the incoming Gold code sequence to generate the fifth result. The processing logic performs a seventh XOR operation of a second delayed version of the second result and the incoming Gold code sequence to generate the sixth result. The processing logic synchronizes the third result and the fourth result by delaying the third result by a third delay amount and delaying the fourth result by a fourth delay amount. The processing logic synchronizes the fifth result and the sixth result by delaying the fifth result by a fifth delay amount and the sixth result by a sixth delay amount.

In at least one embodiment, the processing logic generates the incoming Gold code sequence by receiving a first PRBS, receiving a second PRBS, delaying the second PRBS to obtain a third PRBS, and performing an XOR operation using the first PRBS and the third PRBS to obtain the incoming Gold code sequence.

The processing logic can perform other operations as described herein in method 900.

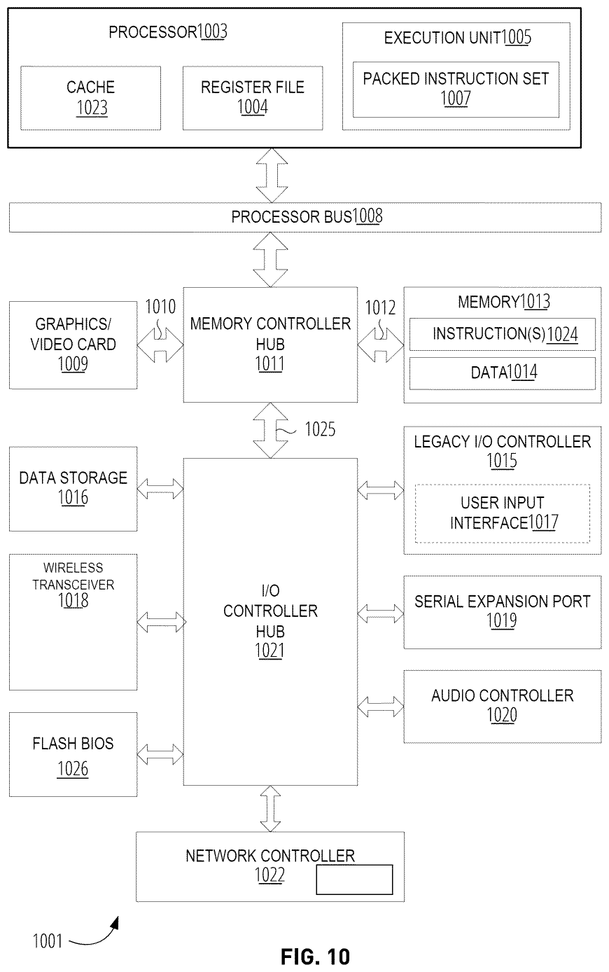

FIG. 10 illustrates an example computer system 1001, including an error correction circuit 140, in accordance with at least some embodiments. In at least one embodiment, computer system 1001 may be a system with interconnected devices and components, an SOC, or some combination. In at least one embodiment, computer system 1001 is formed with a processor 1003 that may include execution units to execute an instruction. In at least one embodiment, computer system 1001 may include, without limitation, a component, such as a processor 1003, to employ execution units including logic to perform algorithms for processing data. In at least one embodiment, computer system 1001 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 1001 may execute a version of WINDOWS' operating system available from Microsoft Corporation of Redmond, Wash., although other operating systems (UNIX and Linux, for example), embedded software, and/or graphical user interfaces, may also be used.

In at least one embodiment, computer system 1001 may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (DSP), an SoC, network computers (“NetPCs”), set-top boxes, network hubs, wide area network (“WAN”) switches, or any other system that may perform one or more instructions. In an embodiment, computer system 1001 may be used in devices such as graphics processing units (GPUs), network adapters, central processing units, and network devices such as switches (e.g., a high-speed direct GPU-to-GPU interconnect such as the NVIDIA GH100 NVLINK or the NVIDIA Quantum 2 64 Ports InfiniBand NDR Switch).

In at least one embodiment, computer system 1001 may include, without limitation, processor 1003 that may include, without limitation, one or more execution units 1005 that may be configured to execute a Compute Unified Device Architecture (“CUDA”) (CUDA® is developed by NVIDIA Corporation of Santa Clara, CA) program. In at least one embodiment, a CUDA program is at least a portion of a software application written in a CUDA programming language. In at least one embodiment, computer system 1001 is a single processor desktop or server system. In at least one embodiment, computer system 1001 may be a multiprocessor system. In at least one embodiment, processor 1003 may include, without limitation, a CISC microprocessor, a RISC microprocessor, a VLIW microprocessor, and a processor implementing a combination of instruction sets, or any other processor device, such as a digital signal processor, for example. In at least one embodiment, processor 1003 may be coupled to a processor bus 1008 that may transmit data signals between processor 1003 and other components in computer system 1001.

In at least one embodiment, processor 1003 may include, without limitation, a Level 1 (“L1”) internal cache memory (“cache”) 1023. In at least one embodiment, processor 1003 may have a single internal cache or multiple levels of internal cache. In at least one embodiment, cache memory may reside external to processor 1003. In at least one embodiment, processor 1003 may also include a combination of both internal and external caches. In at least one embodiment, a register file 1004 may store different types of data in various registers including, without limitation, integer registers, floating point registers, status registers, and instruction pointer register.

In at least one embodiment, execution unit 1005, including, without limitation, logic to perform integer and floating point operations, also resides in processor 1003. Processor 1003 may also include a microcode (“ucode”) read only memory (“ROM”) that stores microcode for certain macro instructions. In at least one embodiment, execution unit 1005 may include logic to handle a packed instruction set 1007. In at least one embodiment, by including packed instruction set 1007 in an instruction set of a general-purpose processor 1003, along with associated circuitry to execute instructions, operations used by many multimedia applications may be performed using packed data in a general-purpose processor 1003. In at least one embodiment, many multimedia applications may be accelerated and executed more efficiently by using full width of a processor's data bus for performing operations on packed data, which may eliminate a need to transfer smaller units of data across a processor's data bus to perform one or more operations one data element at a time.

In at least one embodiment, execution unit 1006 may also be used in microcontrollers, embedded processors, graphics devices, DSPs, and other types of logic circuits. In at least one embodiment, computer system 1001 may include, without limitation, a memory 1013. In at least one embodiment, memory 1013 may be implemented as a DRAM device, an SRAM device, flash memory device, or other memory devices. Memory 1013 may store instruction(s) 1024 and/or data 1014 represented by data signals that may be executed by processor 1003.

In at least one embodiment, a system logic chip may be coupled to a processor bus 1008 and memory 1013. In at least one embodiment, the system logic chip may include, without limitation, a memory controller hub (“MCH”) 1011, and processor 1003 may communicate with MCH 1011 via processor bus 1008. In at least one embodiment, MCH 1011 may provide a high bandwidth memory path 1012 to memory 1013 for instruction and data storage and for storage of graphics commands, data, and textures. In at least one embodiment, MCH 1011 may direct data signals between processor 1003, memory 1013, and other components in computer system 1001 and may bridge data signals between processor bus 1008, memory 1013, and a system I/O 1025. In at least one embodiment, a system logic chip may provide a graphics port for coupling to a graphics controller. In at least one embodiment, MCH 1011 may be coupled to memory 1013 through high bandwidth memory path 1012, and graphics/video card 1009 may be coupled to MCH 1011 through an Accelerated Graphics Port (“AGP”) interconnect 1010.

In at least one embodiment, computer system 1001 may use system I/O 1025 that is a proprietary hub interface bus to couple MCH 1011 to I/O controller hub (“ICH”) 1021. In at least one embodiment, ICH 1021 may provide direct connections to some I/O devices via a local I/O bus. In at least one embodiment, a local I/O bus may include, without limitation, a high-speed I/O bus for connecting peripherals to memory 1013, a chipset, and processor 1003. Examples may include, without limitation, an audio controller 1020, a firmware hub (“flash BIOS”) 726, a wireless transceiver 1018, a data storage 1016, a legacy I/O controller 1015 containing a user input interface 1017, a keyboard interface, a serial expansion port 1019, such as a USB, and a network controller 1022. In at least one embodiment, the network controller 1022 includes the error correction circuit 140. The error correction circuit 140 can be the error correction circuit 200 of FIG. 2 or the error correction circuit 700 of FIG. 7. Data storage 1016 may comprise a hard disk drive, a floppy disk drive, a CD-ROM device, a flash memory device, or other mass storage device.

In at least one embodiment, FIG. 10 illustrates a system, which includes interconnected hardware devices or “chips.” In at least one embodiment, FIG. 10 may illustrate an example SoC. In at least one embodiment, devices illustrated in FIG. 10 may be interconnected with proprietary interconnects, standardized interconnects (e.g., PCIe), or some combination thereof. In at least one embodiment, one or more components of system 1002 are interconnected using compute express link (“CXL”) interconnects.

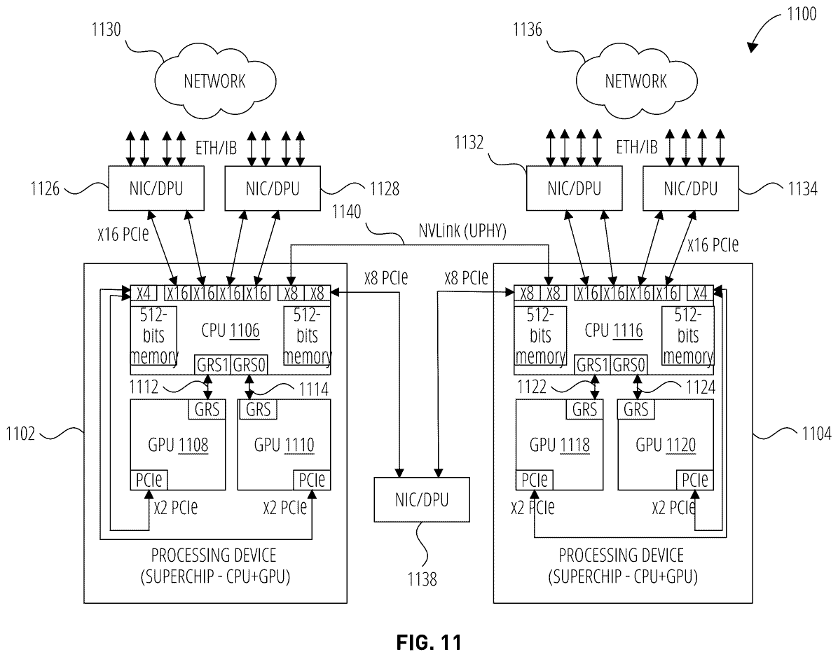

FIG. 11 is a block diagram of a computing system 1100 having two processing devices coupled to each other and multiple networks according to at least one embodiment. The computing system 1100 is designed with multiple integrated circuits (referred to as processing devices), where each integrated circuit includes a CPU and two GPUs, forming a powerful and flexible architecture. These processing devices are interconnected via an NVLink (or other high-speed interconnect), enabling high-speed communication between the processing devices, and are also connected through a Network Interface Card (NIC) or Data Processing Unit (DPU) to ensure efficient data transfer across the computing system 1100. The coupling of processing devices through NVLink allows for seamless data exchange and parallel processing, enhancing overall computational performance. Additionally, these processing devices are connected to multiple networks through one or more network interface cards (NICs) or DPUs, enabling the system to handle complex, multi-network tasks with high bandwidth and low latency. This configuration makes the computing system 1100 highly suitable for demanding applications that require significant processing power, such as artificial intelligence (AI), machine learning (ML), and data-intensive computing, while ensuring robust connectivity and scalability across various networked environments. The integrated circuits of the computing system 1100 can include one or more CPUs and one or more GPUs. An example architecture of a multi-GPU architecture is illustrated in FIG. 11.

As illustrated in FIG. 11, the computing system 1100 includes a processing device 1102 with a multi-GPU architecture. In particular, the processing device 1102 includes a CPU 1106, a GPU 1108, and a GPU 1110. The CPU 1106 can be coupled to the GPU 1108 via an die-to-die (D2D) or chip-to-chip (C2C) interconnect 1112, such as a Ground-Referenced Signaling interconnect (GRS interconnect). The CPU 1106 can be coupled to the GPU 1110 via a D2D or C2C interconnect 1114. The CPU 1106 can also couple to the GPU 1108 and GPU 1110 via PCIe interconnects. The CPU 1106 can be coupled to one or more network interface cards (NICs) or data processing units (DPUs), which are coupled to one or more networks. For example, as illustrated in FIG. 11, the CPU 1106 is coupled to a first NIC/DPU 1126, which is coupled to a network 1130. The CPU 1106 is also coupled to a second NIC/DPU 1128, which is coupled to the network 1130. The NIC/DPU 1126 and NIC/DPU 1128 can be coupled to the network 1130 over Ethernet (ETH) or InfiniBand (IB) connections.

The computing system 1100 also includes a processing device 1104 with a multi-GPU architecture. In particular, the processing device 1104 includes a CPU 1116, a GPU 1118, and a GPU 1120. The CPU 1116 can be coupled to the GPU 1118 via an D2D or C2C interconnect 1122. The CPU 1116 can be coupled to the GPU 1120 via a D2D or C2C interconnect 1124. The CPU 1116 can also couple to the GPU 1118 and GPU 1120 via PCIe interconnects. The CPU 1116 can be coupled to one or more NICs or DPUs, which are coupled to one or more networks. For example, as illustrated in FIG. 11, the CPU 1116 is coupled to a first NIC/DPU 1132, which is coupled to a network 1136. The CPU 1116 is also coupled to a second NIC/DPU 1134, which is coupled to the network 1136. The NIC/DPU 1132 and NIC/DPU 1134 can be coupled to the network 1136 over Ethernet (ETH) or InfiniBand (IB) connections.

In at least one embodiment, the processing device 1102 and the processing device 1104 can communication with each other via a NIC/DPU 1138, such as over PCIe interconnects. The processing device 1102 and processing device 1104 can also communicate with each other over a high-bandwidth communication interconnects 1140, such as an NVLink interconnect or other high-speed interconnects. The NIC/DPUs of FIG. 11 can be the various embodiments of the DPUs described herein. The error correction circuit 140 can be implemented in any receiver device of any of the devices described herein.

In at least one embodiment, the computing system 1100 is used for high-speed network communication and includes a processing unit (e.g., CPU 1106, GPU 1108, GPU 1110, CPU 1116, GPU 1118, GPU 1120, NIC/DPU 1126, NIC/DPU 1128, NIC/DPU 1132, NIC/DPU 1134, or NIC/DPU 1138), and a network interface coupled to the processing unit. The network interface can include the operations and functionality of the DPUs described herein.

In at least one embodiment, the computing system 1100 includes a host device and an auxiliary device. The auxiliary device includes a device memory and a processor, communicably coupled to the device memory. The auxiliary device performs the operations described herein with respect to FIG. 1 to FIG. 9. The auxiliary device can include a GPU. The auxiliary device can include a DPU. The auxiliary device can include a DPU. The auxiliary device can include accelerator hardware.

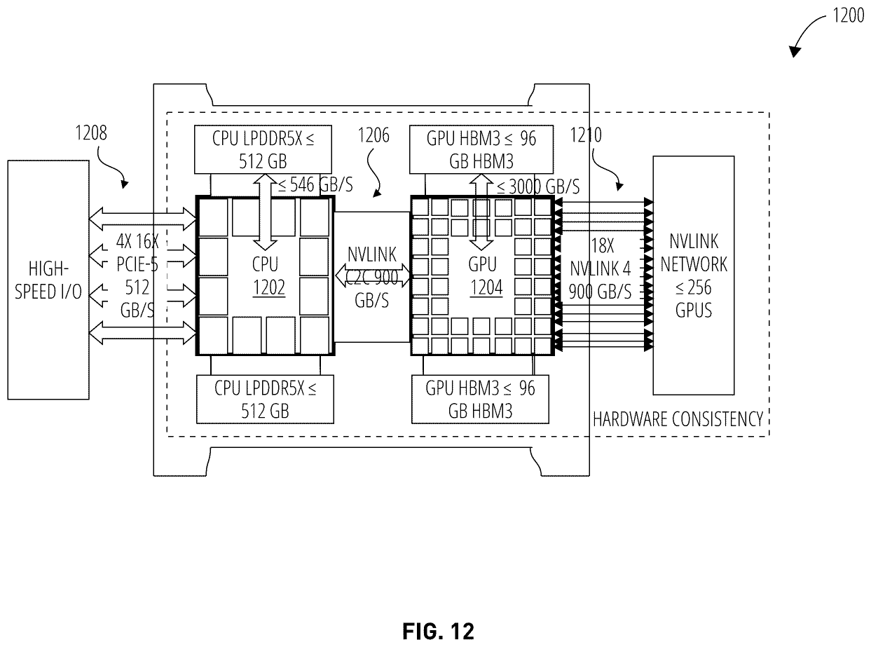

FIG. 12 is a block diagram of a computing system 1200 having a CPU 1202 and a GPU 1204 in a single integrated circuit according to at least one embodiment. The computing system 1200 can be a highly integrated design where a CPU 1202 and GPU 1204 are connected on a single integrated circuit, utilizing an NVLink C2C (Chip-to-Chip) interconnect 1206 to enable fast, low-latency communication between the two processing units. This close integration allows for efficient data transfer and parallel processing between the CPU 1202 and GPU 1204, optimizing performance for complex computational tasks. The GPU elements within the computing system 1200 can be interconnected using an NVLink network, allowing for scalability up to 256 GPU elements, creating a powerful, unified processing environment ideal for large-scale AI, ML, and high-performance computing applications. The NVLink network can be a GPU fabric of high-bandwidth communication interconnects 1210. Additionally, the computing system 1200 can be designed to interface with a high-speed I/O through PCIe interconnects 1208, ensuring rapid data transfer to and from external devices, further enhancing the system's capabilities in handling data-intensive tasks and providing robust connectivity to peripheral components. It should be noted that the C2C interconnects 1206 can be considered D2D interconnects since the CPU 1202 and the GPU 1204 are located on the same integrated circuit. The integrated circuit can include CPU memory (also referred to as main memory) and GPU memory, which are accessible by the CPU 1202 and the GPU 1204, respectively, over high-speed interconnects. The computing system 1200 can bring together performance of the GPU 1204 with the versatility of the CPU 1202. The CPU 1202 can be connected with a high-bandwidth and memory coherent C2C interconnects 1206 in a single integrated circuit. The computing system 1200 can support a link switch system.

The computing system 1200 can include the error correction circuit 140 used for the various embodiments described herein with respect to FIG. 1 to FIG. 9. The error correction circuit 140 can be implemented in any receiver device of any of the devices described herein.

In at least one embodiment, the computing system 1200 is used for high-speed network communication and includes a processing unit, and a network interface coupled to the processing unit. The network interface can include the operations and functionality of the DPUs described herein.

In at least one embodiment, the computing system 1200 includes a host device and an auxiliary device. The auxiliary device includes a device memory and a processor, communicably coupled to the device memory. The auxiliary device performs the operations described herein with respect to FIG. 1 to FIG. 9. The auxiliary device can include a GPU. The auxiliary device can include a DPU. The auxiliary device can include a DPU. The auxiliary device can include accelerator hardware.

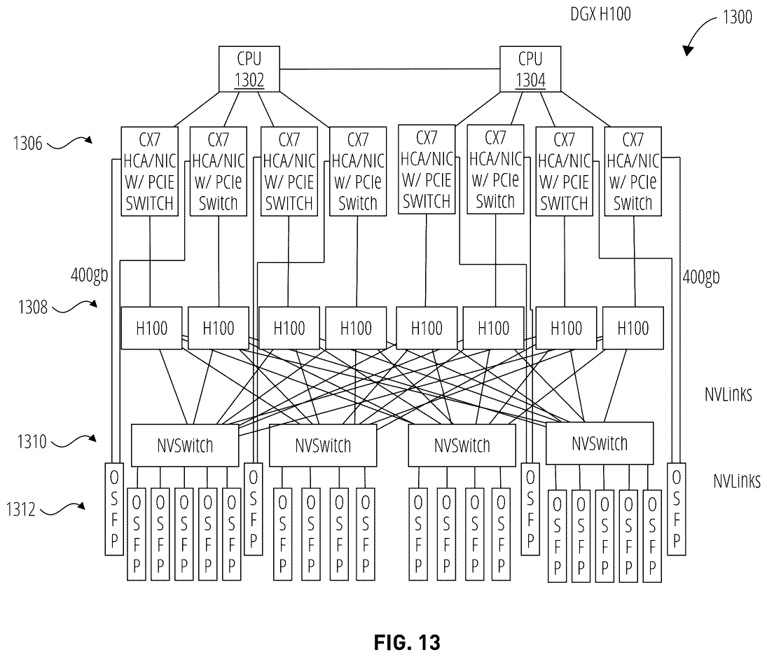

FIG. 13 is a block diagram of a computing system 1300 having tensor core GPUs 1308 according to at least one embodiment. The computing system 1300 can be a DGX H100 system, which is a high-performance computing platform designed to meet the demands of AI, ML, and deep learning (DL) workloads. The computing system 1300 can include multiple tensor core GPUs 1308 (e.g., NVIDIA H100 Tensor Core GPUs). The tensor core GPUs 1308 can each be one of the integrated circuits described above with respect to FIG. 12. The tensor core GPUs 1308 can be optimized for AI/ML/DL applications, offering exceptional performance for deep learning training, inference, and high-performance computing tasks. The tensor core GPUs 1308 within the computing system 1300 are interconnected using high-speed communication interfaces like NVLinks, enabling rapid data transfer between them, which is crucial for handling large-scale AI models and datasets with low latency. This computing system 1300 is designed for scalability, allowing for the integration of additional GPUs as required, making it versatile enough for research, development, and deployment in data centers for production AI workloads. Each GPU is equipped with Tensor Cores, specialized processing units that accelerate matrix operations, a fundamental component of AI and deep learning algorithms. These Tensor Cores enable the system to perform mixed-precision calculations efficiently, balancing speed and accuracy. Given the power consumption and heat generation of multiple tensor core GPUs 1308, the computing system 1300 can include advanced cooling solutions and power management features to ensure safe operation while maintaining peak performance. It is supported by a comprehensive software ecosystem, including NVIDIA's CUDA programming model, AI frameworks like TensorFlow and PyTorch, and other HPC and AI software tools, which enable developers and researchers to harness the full power of the tensor core GPUs 1308 for their specific applications. The computing system 1300 is ideally suited for large-scale AI model training, real-time inference, scientific simulations, data analytics, and other compute-intensive tasks that require massive parallel processing power.

The tensor core GPUs 1308 can be coupled to multiple CPUs, such as CPU 1302 and CPU 1304, using switches 1306 (e.g., CX7 HCA/NIC with PCIe switch). The tensor core GPUs 1308 can be coupled to each other via switches 1310 (e.g., NVSwitches). The switches 1306 and switches 1310 can be coupled to high-speed transceiver modules 1312. The high-speed transceiver modules 1312 can be Octal Small Form-factor Pluggable (OSFP) modules. OSFP modules refer to high-speed transceiver modules designed for rapid data communication, particularly in environments requiring significant bandwidth, such as data centers and high-performance computing systems. These modules support extremely high data rates, typically up to 400 Gbps per module, with future capabilities extending to 800 Gbps or more. OSFP modules interface with the system via the PCIe interface, enabling fast and efficient data transfer between the integrated CPU-GPU components and external networks or other connected systems. Their hot-pluggable nature allows for easy insertion or removal without the need to power down the system, offering flexibility and ease of maintenance, which is crucial in critical-uptime environments. Additionally, OSFP modules are designed for high density, maximizing the number of high-speed connections within limited space, such as in densely packed server racks. By adhering to the latest networking standards, OSFP modules ensure the computing system 1300 remains capable of meeting increasing data demands and can be upgraded to support future advancements in network speeds, thus contributing to the system's overall performance and scalability.

In at least one embodiment, the computing system 1300 can be considered a data-network configuration with full-bandwidth intra-server NVLinks. In this example, all eight tensor core GPUs 1308 can simultaneously saturate eighteen NVLinks to other GPUs within the server. The bandwidth is limited by over-subscription from multiple other GPUs. In another embodiments, data-network configuration can be a half-bandwidth intra-server NVLinks. In this example, all eight tensor core GPUs 1308 can half-subscribe eighteen NVLinks to GPUs in other servers. Four tensor core GPUs 1308 can saturate eighteen NVLinks to GPUs in other servers. This is equivalent of full-bandwidth on AllReduce with Scalable Hierarchical Aggregation and Reduction Protocol (SHARP). The reduction in all-2-all (All2All) bandwidth is a balance with server complexity and costs. In at least one embodiment, all eight tensor core GPUs 1308 can independently transfer data, using Remote Direct Memory Access (RDMA) protocol, over its own dedicated switch (e.g., 400 Gb/s HCA/NIC) in an multi-rail InfiniBand/Ethernet configuration. In this example, 800 GBps of aggregate full-duplex to non-NVLink network devices.

The NICs/switches of computing system 1300 can include the various embodiments described herein with respect to FIG. 1 to FIG. 9.

In at least one embodiment, the computing system 1300 is used for high-speed network communication and includes a processing unit (e.g., CPU 1302, CPU 1304, switches 1306, tensor core GPUs 1308, switches 1310, high-speed transceiver modules 1312), and a network interface coupled to the processing unit. The network interface can include a receiver or a transceiver and perform the corresponding operations and functionalities described herein. The processing unit can include a CPU, a GPU, a DPU, a network adapter, a network switch, an NVLink switch, or the like.

In at least one embodiment, the computing system 1300 includes a host device and an auxiliary device. The auxiliary device includes a device memory and a processor, communicably coupled to the device memory. The auxiliary device performs the operations described herein with respect to FIG. 1 to FIG. 9. The auxiliary device can include a GPU. The auxiliary device can include a DPU. The auxiliary device can include a DPU. The auxiliary device can include accelerator hardware.

Other variations are within the spirit of the present disclosure. Thus, while disclosed techniques are susceptible to various modifications and alternative constructions, certain illustrated embodiments thereof are shown in drawings and have been described above in detail. It should be understood, however, that there is no intention to limit the disclosure to a specific form or forms disclosed, but on the contrary, the intention is to cover all modifications, alternative constructions, and equivalents falling within the spirit and scope of the disclosure, as defined in appended claims.

Use of terms “a” and “an” and “the” and similar referents in the context of describing disclosed embodiments (especially in the context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. The term “connected,” when unmodified and referring to physical connections, is to be construed as partly or wholly contained within, attached to, or joined together, even if there is something intervening. Recitations of ranges of values herein are merely intended to serve as a shorthand method of referring individually to each separate value falling within range unless otherwise indicated herein, and each separate value is incorporated into the specification as if it were individually recited herein. Use of the term “set” (e.g., “a set of items”) or “subset,” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but subset and corresponding set may be equal.

Conjunctive language, such as phrases of the form “at least one of A, B, and C,” or “at least one of A, B, and C,” unless specifically stated otherwise or otherwise clearly contradicted by context, is otherwise understood with the context as used in general to present that an item, term, etc., may be either A or B or C, or any nonempty subset of a set of A and B and C. For instance, in the illustrative example of a set having three members, conjunctive phrases “at least one of A, B, and C” and “at least one of A, B, and C” refers to any of the following sets:
{A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, the term “plurality” indicates a state of being plural (e.g., “a plurality of items” indicates multiple items). A plurality is at least two items but can be more when so indicated either explicitly or by context. Further, unless stated otherwise or otherwise clear from context, the phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under the control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause a computer system to perform operations described herein. A set of non-transitory computer-readable storage media, in at least one embodiment, comprises multiple non-transitory computer-readable storage media, and one or more individual non-transitory storage media of multiple non-transitory computer-readable storage media lack all of the code while multiple non-transitory computer-readable storage media collectively store all of the code. In at least one embodiment, executable instructions are executed such that different instructions are executed by different processors-for example, a non-transitory computer-readable storage medium stores instructions, and a main CPU executes some of the instructions while a GPU executes other instructions. In at least one embodiment, different components of a computer system have separate processors, and different processors execute different subsets of instructions.

Accordingly, in at least one embodiment, computer systems are configured to implement one or more services that singly or collectively perform operations of processes described herein, and such computer systems are configured with applicable hardware and/or software that enable the performance of operations. Further, a computer system that implements at least one embodiment of present disclosure is a single device and, in another embodiment, is a distributed computer system comprising multiple devices that operate differently such that the distributed computer system performs operations described herein and such that a single device does not perform all operations.

Use of any and all examples, or exemplary language (e.g., “such as”) provided herein, is intended merely to better illuminate embodiments of the disclosure, and does not pose a limitation on the scope of the disclosure unless otherwise claimed. No language in the specification should be construed as indicating any non-claimed element as essential to the practice of the disclosure.

All references, including publications, patent applications, and patents, cited herein are hereby incorporated by reference to the same extent as if each reference were individually and specifically indicated to be incorporated by reference and were set forth in its entirety herein.

The terms “coupled” and “connected,” along with their derivatives, may be used in the description and claims. It should be understood that these terms may not be intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other but yet still CO-operate or interact with each other.

Unless specifically stated otherwise, it may be appreciated that throughout specification terms such as “processing,” “computing,” “calculating,” “determining,” or like, refer to action and/or processes of a computer or computing system or similar electronic computing devices, that manipulate and/or transform data represented as physical, such as electronic, quantities within computing system's registers and/or memories into other data similarly represented as physical quantities within computing system's memories, registers or other such information storage, transmission or display devices.

In a similar manner, the term “processor” may refer to any device or portion of a device that processes electronic data from registers and/or memory and transforms that electronic data into other electronic data that may be stored in registers and/or memory. As non-limiting examples, a “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes for carrying out instructions in sequence or parallel, continuously, or intermittently. The terms “system” and “method” are used herein interchangeably as far as a system may embody one or more methods, and methods may be considered a system.

In the present document, references may be made to obtaining, acquiring, receiving, or inputting analog or digital data into a subsystem, computer system, or computer-implemented machine. Obtaining, acquiring, receiving, or inputting analog and digital data can be accomplished in a variety of ways, such as by receiving data as a parameter of a function call or a call to an application programming interface. In some implementations, the process of obtaining, acquiring, receiving, or inputting analog or digital data can be accomplished by transferring data via a serial or parallel interface. In another implementation, the process of obtaining, acquiring, receiving, or inputting analog or digital data can be accomplished by transferring data via a computer network from providing entity to acquiring entity. References may also be made to providing, outputting, transmitting, sending, or presenting analog or digital data. In various examples, the process of providing, outputting, transmitting, sending, or presenting analog or digital data can be accomplished by transferring data as an input or output parameter of a function call, a parameter of an application programming interface, or inter-process communication mechanism.

Although the discussion above sets forth example implementations of described techniques, other architectures may be used to implement the described functionality and are intended to be within the scope of this disclosure. Furthermore, although specific distributions of responsibilities are defined above for purposes of discussion, various functions and responsibilities might be distributed and divided in different ways, depending on circumstances.

Furthermore, although the subject matter has been described in language specific to structural features and/or methodological acts, it is to be understood that the subject matter claimed in appended claims is not necessarily limited to specific features or acts described. Rather, specific features and acts are disclosed as exemplary forms of implementing the claims.

What is claimed is:

1. A receiver device comprising:
an error correction circuit to receive an incoming Gold code sequence, the incoming Gold code sequence comprising an error at a specific bit position, wherein the error correction circuit is to:
generate a plurality of Gold code sequences using the incoming Gold code sequence and delayed versions of the incoming Gold code sequence, each delayed version being delayed by a different amount such that each of the plurality of Gold code sequences comprises errors at different bit positions than the specific bit position; and
generate a corrected Gold code sequence using the plurality of Gold code sequences.

2. The receiver device of claim 1, wherein the error correction circuit, to generate the plurality of Gold code sequences, is further to:
perform a first exclusive OR (XOR) operation of the incoming Gold code sequence and a first delayed version of the incoming Gold code sequence to obtain a first result;
perform a second XOR operation of the incoming Gold code sequence and a second delayed version of the incoming Gold code sequence to obtain a second result, wherein a first delay amount associated with the first delayed version of the incoming Gold code sequence is different than a second delay amount associated with the second delayed version of the incoming Gold code sequence;
generate and synchronize a third result and a fourth result using the first result; and
generate and synchronize a fifth result and a sixth result using the second result.

3. The receiver device of claim 2, wherein the error correction circuit, to generate the corrected Gold code sequence, is further to:
make a first majority vote decision for each respective bit in the third result and the fifth result;
make a second majority vote decision for each respective bit in the fourth result and the sixth result; and
perform a third XOR operation of the first majority vote decision and the second majority vote decision for each bit in the corrected Gold code sequence.

4. The receiver device of claim 2, wherein the error correction circuit, to generate the plurality of Gold code sequences, is further to:
perform a fourth XOR operation of a first delayed version of the first result and the incoming Gold code sequence to generate the third result;
perform a fifth XOR operation of a second delayed version of the first result and the incoming Gold code sequence to generate the fourth result;
perform a sixth XOR operation of a first delayed version of the second result and the incoming Gold code sequence to generate the fifth result;
perform a seventh XOR operation of a second delayed version of the second result and the incoming Gold code sequence to generate the sixth result;
synchronize the third result and the fourth result by delaying the third result by a third delay amount and delaying the fourth result by a fourth delay amount; and
synchronize the fifth result and the sixth result by delaying the fifth result by a fifth delay amount and the sixth result by a sixth delay amount.

5. The receiver device of claim 1, wherein the incoming Gold code sequence is generated by:
receiving a first pseudo-random binary sequence (PRBS);
receiving a second PRBS;
delaying the second PRBS to obtain a third PRBS; and
performing an exclusive OR (XOR) operation using the first PRBS and the third PRBS to obtain the incoming Gold code sequence.

6. A system for high-speed network communication, the system comprising:
a processing unit; and
a network interface coupled to the processing unit, wherein the network interface comprises a receiver device comprising an error correction circuit to an incoming Gold code sequence, the incoming Gold code sequence comprising an error at a specific bit position, wherein the error correction circuit is to:
generate a plurality of Gold code sequences using the incoming Gold code sequence and delayed versions of the incoming Gold code sequence, each delayed version being delayed by a different amount such that each of the plurality of Gold code sequences comprises errors at different bit positions than the specific bit position; and
generate a corrected Gold code sequence using the plurality of Gold code sequences.

7. The system of claim 6, wherein the processing unit comprises at least one of a central processing unit (CPU), a graphics processing unit (GPU), a data processing unit (DPU), a network adapter, a network switch, or an NVLink switch.

8. The system of claim 6, wherein the error correction circuit, to generate the plurality of Gold code sequences, is further to:
perform a first exclusive OR (XOR) operation of the incoming Gold code sequence and a first delayed version of the incoming Gold code sequence to obtain a first result;
perform a second XOR operation of the incoming Gold code sequence and a second delayed version of the incoming Gold code sequence to obtain a second result, wherein a first delay amount associated with the first delayed version of the incoming Gold code sequence is different than a second delay amount associated with the second delayed version of the incoming Gold code sequence;
generate and synchronize a third result and a fourth result using the first result; and
generate and synchronize a fifth result and a sixth result using the second result.

9. The system of claim 8, wherein the error correction circuit, to generate the corrected Gold code sequence, is further to:
make a first majority vote decision for each respective bit in the third result and the fifth result;
make a second majority vote decision for each respective bit in the fourth result and the sixth result; and
perform a third XOR operation of the first majority vote decision and the second majority vote decision for each bit in the corrected Gold code sequence.

10. The system of claim 8, wherein the error correction circuit, to generate the plurality of Gold code sequences, is further to:
perform a fourth XOR operation of a first delayed version of the first result and the incoming Gold code sequence to generate the third result;
perform a fifth XOR operation of a second delayed version of the first result and the incoming Gold code sequence to generate the fourth result;
perform a sixth XOR operation of a first delayed version of the second result and the incoming Gold code sequence to generate the fifth result;
perform a seventh XOR operation of a second delayed version of the second result and the incoming Gold code sequence to generate the sixth result;
synchronize the third result and the fourth result by delaying the third result by a third delay amount and delaying the fourth result by a fourth delay amount; and
synchronize the fifth result and the sixth result by delaying the fifth result by a fifth delay amount and the sixth result by a sixth delay amount.

11. The system of claim 6, wherein the incoming Gold code sequence is generated by:
receiving a first pseudo-random binary sequence (PRBS);
receiving a second PRBS;
delaying the second PRBS to obtain a third PRBS; and
performing an exclusive OR (XOR) operation using the first PRBS and the third PRBS to obtain the incoming Gold code sequence.

12. A method comprising:
receiving an incoming Gold code sequence, the incoming Gold code sequence comprising an error at a specific bit position;
generating a plurality of Gold code sequences using the incoming Gold code sequence and delayed versions of the incoming Gold code sequence, each delayed version being delayed by a different amount such that each of the plurality of Gold code sequences comprises errors at different bit positions than the specific bit position; and
generating a corrected Gold code sequence using the plurality of Gold code sequences.

13. The method of claim 12, wherein generating the plurality of Gold code sequences comprises:
performing a first exclusive OR (XOR) operation of the incoming Gold code sequence and a first delayed version of the incoming Gold code sequence to obtain a first result;
performing a second XOR operation of the incoming Gold code sequence and a second delayed version of the incoming Gold code sequence to obtain a second result, wherein a first delay amount associated with the first delayed version of the incoming Gold code sequence is different than a second delay amount associated with the second delayed version of the incoming Gold code sequence;
generating and synchronizing a third result and a fourth result using the first result; and
generating and synchronizing a fifth result and a sixth result using the second result.

14. The method of claim 13, wherein generating the corrected Gold code sequence further comprises:
making a first majority vote decision for each respective bit in the third result and the fifth result;
making a second majority vote decision for each respective bit in the fourth result and the sixth result; and
performing a third XOR operation of the first majority vote decision and the second majority vote decision for each bit in the corrected Gold code sequence.

15. The method of claim 13, wherein generating the corrected Gold code sequence further comprises:
performing a fourth XOR operation of a first delayed version of the first result and the incoming Gold code sequence to generate the third result;
performing a fifth XOR operation of a second delayed version of the first result and the incoming Gold code sequence to generate the fourth result;
performing a sixth XOR operation of a first delayed version of the second result and the incoming Gold code sequence to generate the fifth result;
performing a seventh XOR operation of a second delayed version of the second result and the incoming Gold code sequence to generate the sixth result;
synchronizing the third result and the fourth result by delaying the third result by a third delay amount and delaying the fourth result by a fourth delay amount; and
synchronizing the fifth result and the sixth result by delaying the fifth result by a fifth delay amount and the sixth result by a sixth delay amount.

16. The method of claim 12, wherein generating the incoming Gold code sequence comprises:
receiving a first pseudo-random binary sequence (PRBS);
receiving a second PRBS;
delaying the second PRBS to obtain a third PRBS; and
performing an exclusive OR (XOR) operation using the first PRBS and the third PRBS to obtain the incoming Gold code sequence.

17. A receiver device comprising:
physical layer logic to receive an incoming Gold code sequence over a channel, the incoming Gold code sequence comprising an error at a specific bit position; and
datalink layer logic coupled to the physical layer logic, wherein the datalink layer logic is to:
generate a plurality of Gold code sequences using the incoming Gold code sequence and delayed versions of the incoming Gold code sequence, each delayed version being delayed by a different amount such that each of the plurality of Gold code sequences comprises errors at different bit positions than the specific bit position; and
generate a corrected Gold code sequence using the plurality of Gold code sequences.

18. The receiver device of claim 17, wherein the datalink layer logic, to generate the plurality of Gold code sequences, is further to:
perform a first exclusive OR (XOR) operation of the incoming Gold code sequence and a first delayed version of the incoming Gold code sequence to obtain a first result;
perform a second XOR operation of the incoming Gold code sequence and a second delayed version of the incoming Gold code sequence to obtain a second result, wherein a first delay amount associated with the first delayed version of the incoming Gold code sequence is different than a second delay amount associated with the second delayed version of the incoming Gold code sequence;
generate and synchronize a third result and a fourth result using the first result; and
generate and synchronize a fifth result and a sixth result using the second result.

19. The receiver device of claim 18, wherein the datalink layer logic, to generate the corrected Gold code sequence, is further to:
make a first majority vote decision for each respective bit in the third result and the fifth result;
make a second majority vote decision for each respective bit in the fourth result and the sixth result; and
perform a third XOR operation of the first majority vote decision and the second majority vote decision for each bit in the corrected Gold code sequence.

20. The receiver device of claim 18, wherein the datalink layer logic, to generate the plurality of Gold code sequences, is further to:
perform a fourth XOR operation of a first delayed version of the first result and the incoming Gold code sequence to generate the third result;
perform a fifth XOR operation of a second delayed version of the first result and the incoming Gold code sequence to generate the fourth result;
perform a sixth XOR operation of a first delayed version of the second result and the incoming Gold code sequence to generate the fifth result;
perform a seventh XOR operation of a second delayed version of the second result and the incoming Gold code sequence to generate the sixth result;
synchronize the third result and the fourth result by delaying the third result by a third delay amount and delaying the fourth result by a fourth delay amount; and
synchronize the fifth result and the sixth result by delaying the fifth result by a fifth delay amount and the sixth result by a sixth delay amount.
